(19) United States
(12) Patent Application Publication
(10) Pub. No.: US 2015/0331031 A1
(43) Pub. Date: Nov. 19, 2015

(54) METHODS, SYSTEMS, AND COMPUTER READABLE MEDIA FOR DETECTING AND LOCATING ONE OR MORE WIRING DEFECT IN DEDICATED AIRCRAFT SYSTEMS

(71) Applicant: AIRBUS (S.A.S), Blagnac (FR)

(72) Inventors: Jean-Luc BARRE, COLOMIERS (FR); Joana BEL, TOULOUSE (FR); Laurent SAISSI, POUCHARRAMET (FR); Benjamin CATOIRE, TOULOUSE (FR)

(21) Appl. No.: 14/567,705

(22) Filed: Dec. 11, 2014

Related U.S. Application Data
(60) Provisional application No. 61/993,148, filed on May 14, 2014.

(51) Int. Cl. G01R 31/00; G01R 31/08

(52) U.S. Cl. CPC G01R 31/008; G01R 31/088

(57) ABSTRACT

Methods, systems, and computer readable media are disclosed for detecting and locating one or more wiring defect in at least one dedicated system of an aircraft, for example and without limitation, using a system testing tool to detect and locate one or more wiring defect in at least one dedicated system of an aircraft. In some aspects, the method includes using the system testing tool for generating data from the at least one system of the aircraft. In addition, the method also includes using the system testing tool for comparing the data with equivalent reference data, as well as for automatically detecting a presence or an absence of one or more wiring defect in the at least one system of the aircraft. Where one or more wiring defect is present in the at least one system, the system testing tool automatically locates the one or more wiring defect

### REFERENCE TO RELATED APPLICATION

This application claims the benefit of U.S. Provisional Application No. 61/993,148, filed on May 14, 2014, the disclosure of which is incorporated herein by reference in its entirety.

### TECHNICAL FIELD

The subject matter described herein relates generally to wiring checking in aircrafts. More particularly, the subject matter disclosed herein relates to methods, systems, and computer readable media for detecting and locating wiring defects in dedicated aircraft systems.

### BACKGROUND

Wiring checks are a challenge for airline operators and aircraft manufacturers due to the numerous permanent defects (e.g., open circuits, short circuits, bounding issues, grounding issues, etc.) or intermittent defects (e.g., contaminated connector pins, insulation scratches, etc.) on wires that may appear anywhere in an electrical wiring system. Detecting and locating such defects is also challenging due, in part, to the length of the wires, the number of wires to be tested, the different types of wires, the different materials used for each wire, etc. Added to these technical difficulties is the frequency to which these issues are encountered, as there may be many events a year, of which some cases may need on-site assistance from the aircraft manufacturers. As a result, airline operators and aircraft manufacturers spend a large amount of time and resources in completing wiring checks, which in turn results in significant costs for the airline operators and/or the aircraft manufacturers.

Accordingly, there exists a need for methods, systems, and computer readable media for detecting and locating wiring defects in dedicated aircraft systems, in order to complete wiring checks in a timely and cost-effective manner.

### SUMMARY

Methods, systems, and computer readable media for detecting and locating wiring defects in dedicated aircraft systems are disclosed. According to one aspect, the subject matter described herein comprises a method for detecting and locating one or more wiring defect in at least one system of an aircraft using a system testing tool for generating data from at least one system of the aircraft. The method also comprises using the system testing tool for comparing the tested data with equivalent reference data, as well as for automatically detecting a presence or an absence of one or more wiring defect in at least one system of the aircraft. Specifically, using the system testing tool for automatically detecting the presence or the absence of one or more wiring defect also include automatically locating the one or more wiring defect if there is one present in at least one system.

According to another aspect, the subject matter described herein comprises a system for detecting and locating one or more wiring defect in an aircraft. The system comprises a testing module, which is configured to generate data from the at least one system of the aircraft. The testing module is also configured to compare the data with equivalent reference data, as well as automatically detect a presence or an absence of one or more wiring defect in the at least one system of the aircraft. Specifically, where the testing module is configured to automatically detect the presence or the absence of one or more wiring defect in the at least one system of the aircraft, the testing module automatically detects and locates the one or more wiring defect if there is one present in the at least one system.

As used herein, the terms “function”, “application”, and/or “module” refer to software in combination with hardware and/or firmware for implementing features described herein.

As used herein, the term “node” refers to a physical computing platform including one or more processors and memory.

The subject matter described herein is implemented in software in combination with hardware and/or firmware. For example, the subject matter described herein may be implemented in software executed by one or more processors. In one exemplary implementation, the subject matter described herein may be implemented using a non-transitory computer readable medium having stored thereon computer executable instructions that when executed by the processor of a computer control the computer to perform steps. Exemplary computer readable media suitable for implementing the subject matter described herein includes non-transitory computer readable media such as, for example and without limitation, disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

The subject matter described herein will now be explained with reference to the accompanying drawings, of which:

FIG. 1 is a perspective view illustrating an exemplary aircraft according to an embodiment of the subject matter described herein;

FIG. 2 is a diagram illustrating an exemplary system testing tool for detecting and locating one or more wiring defect in at least one dedicated aircraft system under test;

FIG. 3 is an exemplary wire characteristics measurement electrical image illustrating equivalent reference data generated from another aircraft system that is devoid of one or more wiring defect;

FIG. 4 is an exemplary distance-to-fault measurement electrical image illustrating equivalent reference data generated from another aircraft system that is devoid of one or more wiring defect;

FIG. 5 is a diagram illustrating exemplary measurement tolerances of equivalent reference data generated from another aircraft system that is devoid of one or more wiring defect;

FIG. 6 is an exemplary wire characteristics measurement electrical image illustrating detection of a wiring defect in at least one dedicated aircraft system under test through a comparison between data generated from the dedicated aircraft system under test with equivalent reference data generated from another aircraft system that is devoid of one or more wiring defect;

FIG. 7 is an exemplary distance-to-fault measurement electrical image illustrating location of a wiring defect in at least one dedicated aircraft system under test through a comparison between data generated from the dedicated aircraft system under test with equivalent reference data generated from another aircraft system that is devoid of one or more wiring defect; and

FIG. 8 is a diagram illustrating an exemplary process for detecting and locating one or more wiring defect in at least one dedicated aircraft system under test according to an embodiment of the subject matter described herein.

### DETAILED DESCRIPTION

In accordance with the description herein and exemplary, associated drawings, novel methods, systems, and computer readable media are disclosed for detecting and locating one or more wiring defect in dedicated aircraft systems. Such methods, systems, and computer readable media optimize aircraft availability by reducing aircraft-on-ground (AOG) or out-of-service situations, reducing time needed to detect and locate a wiring defect, reducing rate of fault reoccurrence, reducing unnecessary equipment removal, and reducing costs.

Reference will now be made in detail to exemplary embodiments of the subject matter described herein, examples of which are illustrated in the accompanying drawings. Wherever possible, the same reference numbers will be used throughout the drawings to refer to the same or like parts.

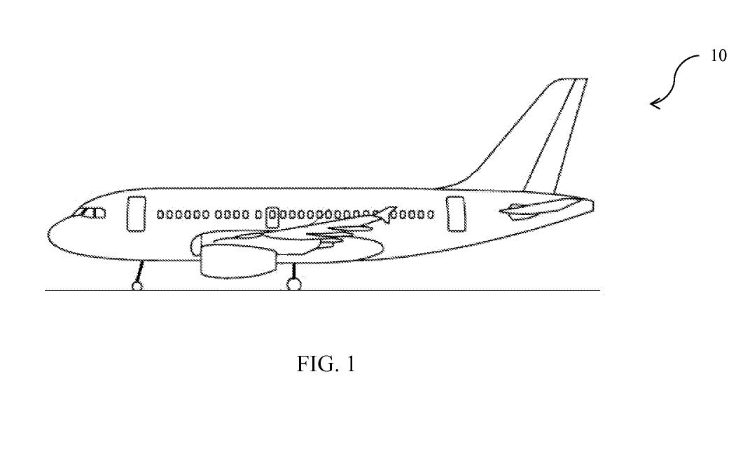

FIG. 1 is a perspective view illustrating an exemplary aircraft 10 according to an embodiment of the subject matter described herein. Aircraft 10 comprises at least one wiring system undergoing a wiring check using the systems, methods, and computer readable media described in the following.

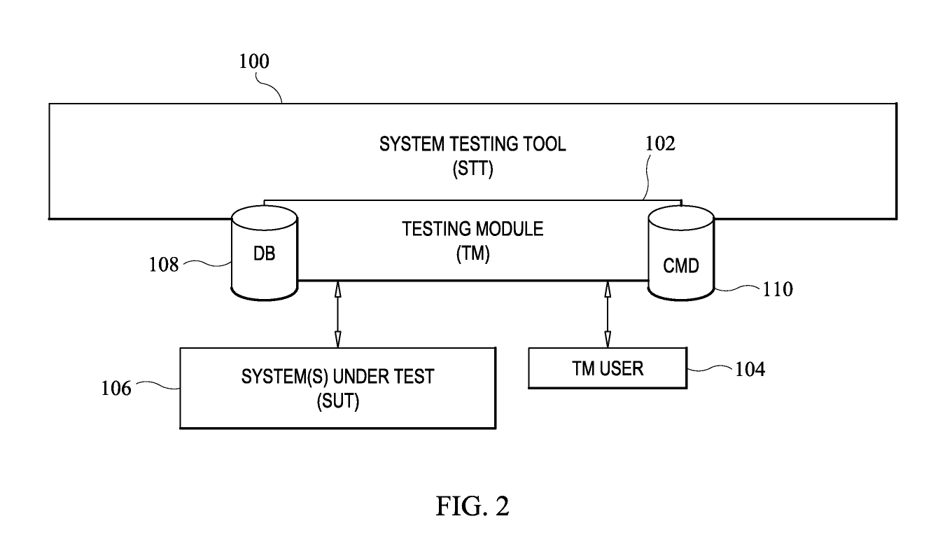

FIG. 2 is a diagram illustrating an exemplary computing platform or system testing tool (STT) 100 for detecting and locating one or more wiring defect in aircraft 10. STT 100 represents any suitable entity or entities (e.g., a testing platform or a server farm) for performing a wiring check in at least one dedicated system of aircraft 10. Performing a wiring check comprises automatically detecting, locating, and/or identifying a presence or an absence of one or more wiring defect in at least one system being tested. Where the presence of one or more wiring defect is found, STT 100 detects and is configured to locate the one or more wiring defect(s) in the system being tested of aircraft 10.

In some aspects, STT 100 is a stand-alone tool, a testing device, or software executing on a processor. In some embodiments, STT 100 is a single node or is distributed across multiple computing platforms or nodes. In some aspects, STT 100 replaces another component of aircraft 10, for e.g., a control unit, in order to test a designated system. For example, STT 100 is a stand-alone device (e.g., a wiring defect detection device) that is connected to the ARINC connector for a dedicated system under test (SUT) 106 in order to check wiring in SUT 106 for both permanent defects and/or intermittent defects, where up to 512 wires are present in SUT 106. SUT 106 in one aspect is any dedicated system or systems within aircraft 100.

In some aspects, permanent defects comprise, for example, open circuits, short circuits, bounding issues, grounding issues, etc., while intermittent defects comprise, for example, contaminated connector pins, twisted wire, shielded twisted wire, etc. STT 100 detects and is configured to detect both types of defects in dedicated systems, where detecting a permanent defect may take less than two hours, while detecting an intermittent defect may take less than one day. Once STT 100 has detected and located one or more defect, it is relatively easy for an engineer or another associated user, to remove only necessary access panel(s) above which the one or more wiring defect is located. This saves time, while also preventing any inadvertent equipment damage.

STT 100 includes a testing module (TM) 102. TM 102 may be any suitable entity (e.g., software executing on a processor) for performing one or more aspects associated with checking the wiring in dedicated aircraft systems. TM 102 includes functionality for automatically detecting and/or locating one or more wiring defect in at least one SUT 106 by running a test script. For example, a test script in one aspect is a transcription of test protocol prepared and/or validated by a manufacturer of aircraft 10, an operator of aircraft 10, or another third party entity associated with aircraft 10. In one non-limiting example, a test protocol is prepared by customer support engineering staff and validated by design office staff. However, any manufacturer, operator, or third party entity associated with aircraft 10 prepares and/or validates the test protocol.

In some aspects, preparing the test protocol comprises an entity (e.g., a customer support engineering staff member) accessing and acquiring data containing information related to preparing test protocol (e.g., lists, test signals, configurations, procedures, validations, certifications, etc.) from data storage. Exemplary data storage may include non-transitory computer readable media, such as flash memory, random access memory, or other storage devices. In some aspects, data storage is external to and/or or integrated with STT 100 and/or TM 102. For example, an entity preparing the test protocol may access and acquire data stored in a database 108, which in one aspect contains configuration information regarding aircraft 10. Database 108 is associated with TM 102 and/or STT 100, and comprises data regarding an initial analysis of the faulty system or SUT 106 of aircraft 10 in terms of end-users installed and electrical configuration (e.g., cable types, wiring routing, etc.). Database 108 may also comprise dedicated test signals that are be defined for each line to be tested (e.g. voltage, current, frequency, duration, etc.) in SUT 106. The entity preparing the test protocol additionally may access and acquire a list of each piece of end-user equipment installed in aircraft 10, validation from an entity (which may be the same as or different than the entity preparing the test protocol) that STT 100 will not damage each piece of end-user equipment installed. This information is obtainable from database 108 or from other data storage in communication with TM 102 and/or STT 100.

In some aspects, validating the test protocol comprises an entity (e.g., a design office staff member) reviewing the prepared test protocol. The validating entity may be the same as or different than the entity validating the test protocol and reviews the test protocol to ensure that the tests are performed with the right procedure, the right testing signals (proof-reading), etc. Once the test protocol is validated by the validating entity, the test protocol is transcribed into the test script to be automatically run by TM 102 on SUT 106.

In addition to providing functionality for automatically detecting and/or locating one or more wiring defect in at least one SUT 106 by running the test script, TM 102 in one aspect includes functionality for storing the test script for future use. For example, TM 102 comprises a configuration management database (CMD) 110 that includes the functionality for storing the test script for future use and providing access for TM 102, as well as other modules, to retrieve the stored test script. CMD 110 includes non-transitory computer readable media, such as flash memory, random access memory, or other storage devices. In some aspects, CMD 110 is external to and/or or integrated with STT 100 and/or TM 102. In other aspects, CMD 110 is configured as both CMD 110 and database 108, such that the configuration information regarding aircraft 10 is also accessibly stored in CMD 110. In the non-limiting example of FIG. 2, CMD 110 and database 108 are depicted as two separate storage devices. However, CMD 110 and database 108 may be one and the same.

In some aspects, TM 102 includes one or more communications interfaces for interacting with users and/or nodes. For example, TM 102 provides a communication interface for communicating with a TM user 104. In some aspects, TM user 104 is an automated system or is controlled or controllable by a human user. For example, TM user 104 connects and/or configures STT 100 with regard to SUT 106. In some aspects, TM 102 is configured to generate and display content (e.g., electrical images) associated with SUT 106 after STT 100 is installed and connected with SUT 106. For example, where STT 100 is a stand-alone device, STT 100 comprises at least one set-up connection harness that TM user 104 installs with SUT 106. In some aspects, installing STT 100 requires removal of a control unit (not shown) with STT 100 and replacement with STT 100 by a TM user 104. Personnel other than TM user 104 may also be tasked with installing STT 100. Thus, TM 102 includes one or more interfaces for interacting with one or more SUT 106.

After STT 100 is installed or connected to SUT 106, TM 102 is configured to run the test script in order to detect and/or locate one or more wiring defect in SUT 106. For example, TM 102 comprises the functionality to simultaneously detect and/or locate one or more wiring defect in all lines of SUT 106. In some instances, SUT 106 has 512 lines. Thus, TM 102 is configurable to simultaneously test 512 lines of SUT 106, although each SUT 106 may have more or less lines. TM 102 is configured to access the test script that is stored in CMD 110. The test script comprises the test protocol prepared and validated by an entity or entities, such as, for example, the manufacturer, operator, or another third party associated with aircraft 10. When TM 102 runs the test script, the test script provides the functionality to generate electrical images of SUT 106. The electrical images generated by TM 102 running the test script provide data to be used in detecting and locating one or more fault or defect in the wiring lines of SUT 106.

Once the electrical images are generated, the generated electrical image feedback is read by an interested party or parties (e.g., TM user 104, service engineers, etc.) via a display interface, which may or may not be provided with STT 100, and/or TM 102. In one aspect, for example, the display interface is integral to STT 100, while in another aspect, for example, the display interface is a component of aircraft 10 or another component remote to aircraft 10. Where the display interface is configured as a component separate from STT 100, STT 100 in one aspect is configured to communicate the generated electrical image feedback to a different device to be uploaded and subsequently displayed. In some aspects, the display interface comprises a user interface (not shown) that allows a user to interact with the data provided by the electrical image feedback.

TM 102 also provides the functionality of recording or storing the generated electrical images in a data storage device in order to track the different wiring configurations of each line of SUT 106. For example, CMD 110 in one aspect is configured to record or store the electrical images generated by TM 102 running the test script, in addition to storing the test script, itself. Alternatively, for example, the generated electrical images are recorded or stored in a storage device, other than CMD 110, that is accessible by STT 100. Where the generated electrical images are recorded or stored in a storage device other than CMD 110, the other storage device is configured to communicate the stored data with one or both of STT 100 and TM 102. In one aspect for example, the storage device (whether it is CMD 110 or another storage device) has an architecture for storing the generated electrical images that comprises:

ATA chapter>Systems specificities>MSN>Operator>Recording date,

where the system specificities comprise optional parts, etc.

In some aspects, both permanent defects and intermittent defects are able to be detected and located using electrical images generated by TM 102, while, conversely, the electrical images generated by TM 102 also detect the absence of any defects in SUT 106. Typically, intermittent defects are less common, but are harder to detect and locate. This is because some intermittent defects have a fault duration greater than one millisecond.

In some exemplary embodiments, the generated electrical images comprise wire characteristics measurements for each line of SUT 106. For example, TM 102 in one aspect comprises a wire characteristics measurement module that runs the test script and generates wire characteristics measurement electrical images. In some aspects, the wire characteristics measurement electrical images are RLC measurements of SUT 106. RLC measurements measure different types of wirings and equipment in SUT 106 using different signals or pulses. For example, when the wire characteristics measurement module runs the test script, the test script is configured to inject a continuous signal or pulse, or a series of signals or pulses down each line of SUT 106. The reflected signal or pulse along each line of SUT 106 is observed in the form of a wire characteristics measurement electrical image.

The wire characteristics measurement electrical image consists of data values for a variety of characteristics being measured by signals or pulses for each line of the system under test. For example, the characteristics include resistance, capacitance, inductance, voltage, frequency, etc., where each characteristic has a defined, standard unit of measurement. In addition, the wire characteristics measurement electrical image includes locations of the high point and/or the low point for each line of the system under test. The wire characteristics measurement electrical image is configured to display in a table format using a display interface that is easily viewable and discernable to a user. A user interface is configured to allow a user, (e.g., TM user 104) to select and view individual, or a select number, of wire characteristics measurements for each line of the system under test. Other user interactions with the wire characteristics measurement electrical image are also contemplated.

In some exemplary embodiments, the electrical images comprise distance-to-fault measurements for each line of the system under test. For example, TM 102 comprises a distance-to-fault measurement module that runs the test script and generates distance-to-fault measurement electrical images. The distance-to-fault measurement electrical images in one aspect consist of a graphical representation of amplitude versus direction for each line of the system under test. In some aspects, the distance-to-fault electrical images of the system under test are reflectometric images of the system. The reflectometric images identify the locations of one or more fault or defect in the wiring of the system under test, where such fault(s) or defect(s) are present, by observing reflected signals or pulses at the wiring interface(s). For example, when the distance-to-fault measurement module runs the test script, the test script is configured to inject a continuous signal or pulse, or a series of signals or pulses down each line of the system under test. The reflected signal or pulse along each line of the system under test is observed in the form of a distance-to-fault measurement electrical image. The location(s) of one or more different defect or fault are observed based on the injected signal or pulse, where such fault(s) or defect(s) are present.

In some aspects, the distance-to-fault measurement electrical image measures and integrates the strength of the return signals or pulses as a function of time in order to plot the line length (distance) for each line of the system under test versus the amplitude of the pulse or signal (amplitude). The amplitude versus distance plot includes data values illustrating significant spike(s) in amplitude. Significant spikes in amplitude are representative of a disruption in the line, whether this disruption is merely a connector, pins, interfaces, etc., or is one or more defect, fault, etc., along each line of the system under test. Determination of what the spike in amplitude is representative of may be dependent on the application of TM 102. For example, where TM 102 is used for merely collecting reference data from a wiring system that is known or be devoid of defects or “healthy”, any spike in amplitude would be representative of a “healthy” disruption or a connector, pin, interface, etc. disposed along the line at an expected location. In comparison, where TM 102 is used on a wiring system that is known to have a defect or suspected of having one or more wiring defect, a spike in amplitude could be representative of either a “healthy” disruption or a defect. Determination of what the spike represents in such a situation will be discussed in further detail below. Thus, the distance-to-fault measurement electrical image provides the location at which any disruptions are located along each line of the system under the test.

Accordingly, in order to automatically detect a presence or an absence of one or more fault in SUT 106 of aircraft 10, the test script is first run on an identical dedicated system of an aircraft devoid of defects or “healthy”, such as, for e.g., an aircraft in final assembly. The test script is run on the healthy aircraft system using a testing device and/or module similar to STT 100 and TM 102, which communicates with and access the test script stored in CMD 100. For example, the test script is accessed via a network from CMD 110. Alternately, the system testing tool is STT 100.

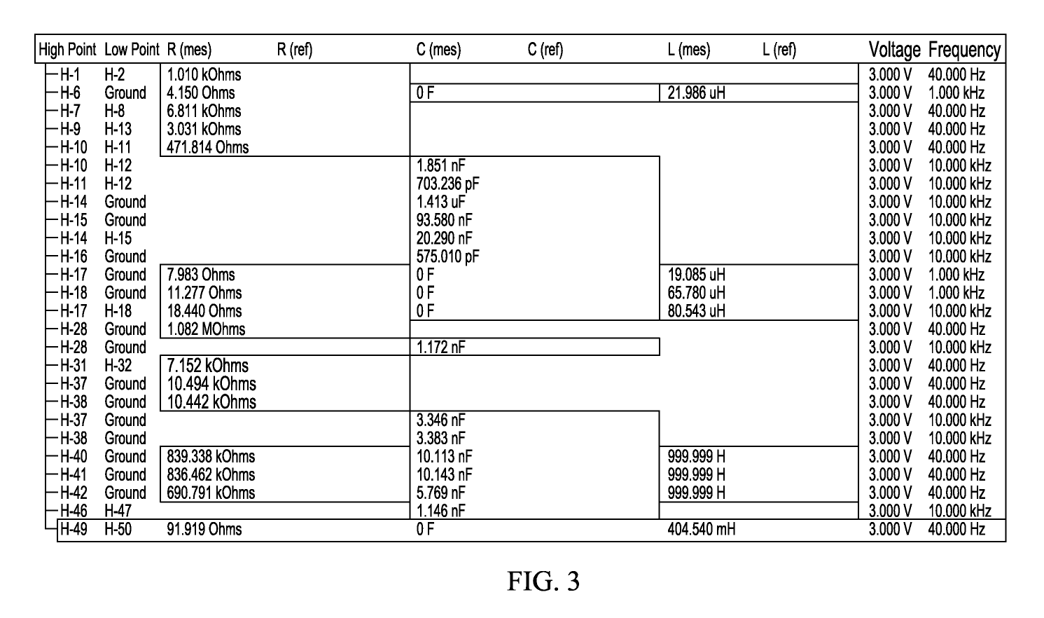

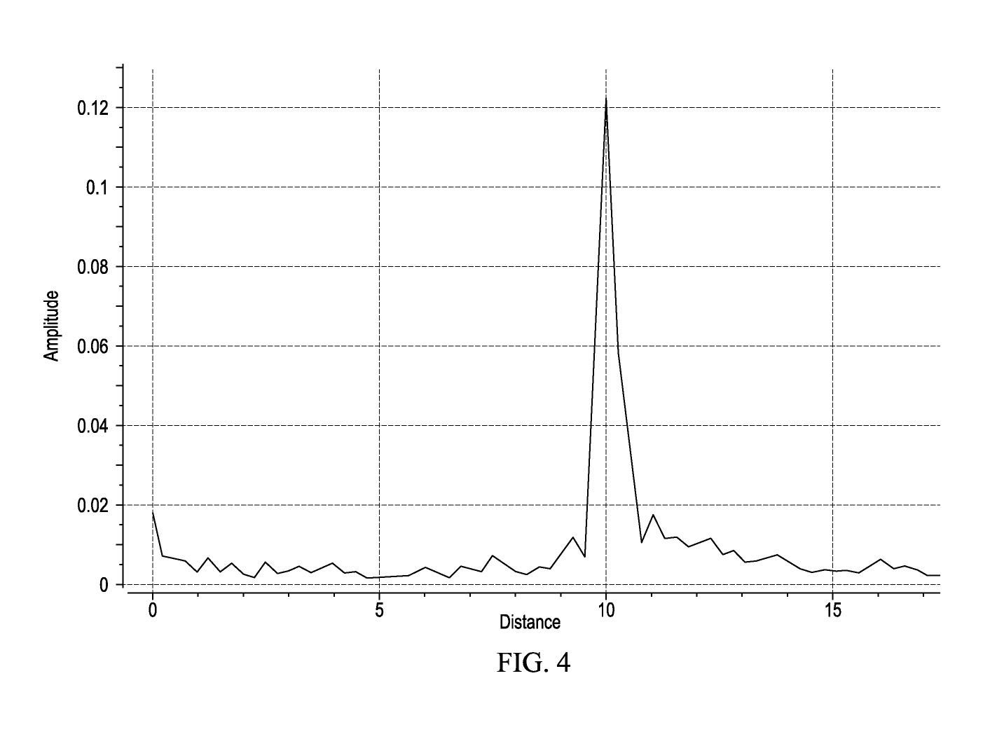

The procedure for running the test script on the identical system in the healthy aircraft requires a test module, such as TM 102, or a test module other than TM 102, to access the test script from storage in CMD 110. The test module, TM 102 or otherwise is configured to run the test script in order to generate electrical images of the identical system. For example, a wire characteristics measurement electrical image and/or a distance-to-fault measurement electrical image is generated by the testing module, which provides reference data of an ideally healthy aircraft system. FIG. 3 illustrates an exemplary reference wire characteristics measurement electrical image of a system of the healthy aircraft, while FIG. 4 illustrates an exemplary reference distance-to-fault measurement electrical image of the same system of the healthy aircraft. As seen in FIG. 4, an amplitude spike at 10 meters along a line (i.e., High Point: J21-4; Low Point: Ground) is representative of a “healthy” disruption, e.g., connector, pin, interface, etc. For example, in FIG. 4, the spike is indicative of a connector located 10 meters along the line. These exemplary reference electrical images are generated and stored in CMD 110 or another data storage that communicates with and is accessible by STT 100 and/or TM 102.

In comparison with generating reference electrical images of the identical system of the healthy aircraft, generating the electrical images of SUT 106 comprises, for example, simultaneously recording the electrical images in CMD 110 and comparing, in real time and without a delay, the generated electrical images against the system configuration stored in database 108. More specifically, TM 102 accesses the system configuration measurements and/or data stored in database 108 and compares those configuration measurements against the real time generation of the electrical images of SUT 106. In some embodiments, recording the electrical images in CMD 110 does not need to be simultaneously accomplished with comparing, in real time and without a delay, the generated electrical images against the system configuration stored in database 108.

Once the test script has been run and electrical images have been generated of the identical system of the healthy aircraft, TM 102 compares the electrical images of SUT 106 with the equivalent reference electrical images. Both sets of electrical images are accessed from DMB 110 or another database where the electrical images are stored in order for analysis to be performed. By comparing the electrical images generated by running the test script on SUT 106 against the equivalent reference electrical images, STT 100 highlights a presence or an absence of any potentially faulty system lines based on previously defined tolerances for each tested line.

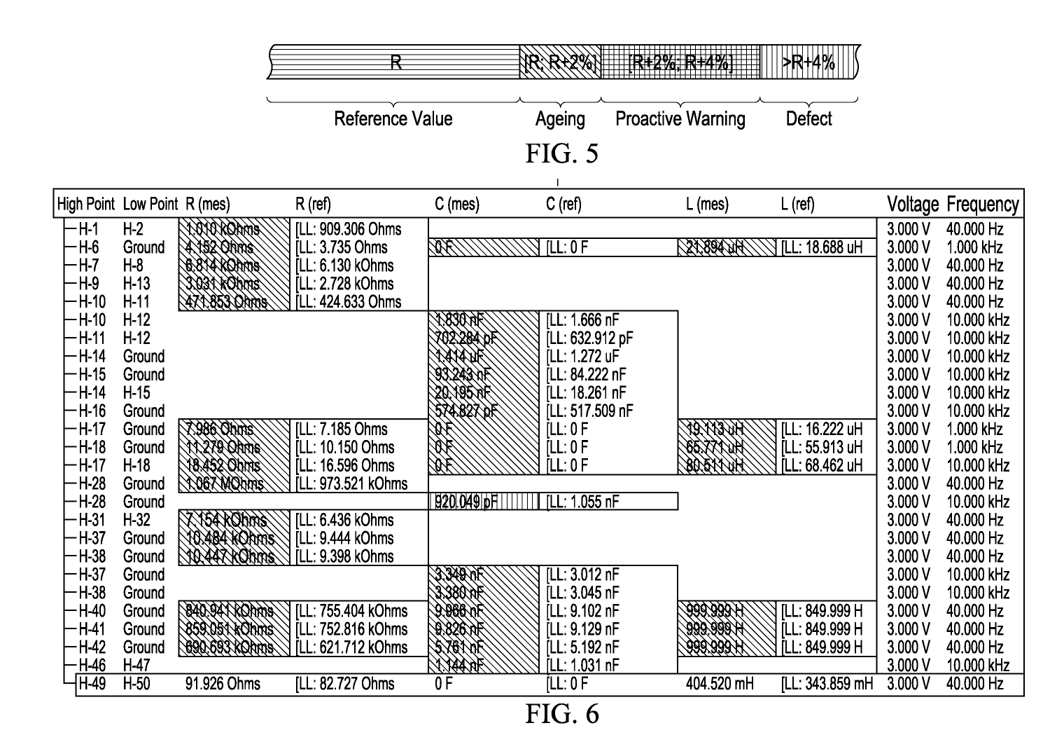

In some aspects, the tolerance for each system line is different, such that some lines may have higher tolerances than other lines. For example, FIG. 5 illustrates an exemplary implementation of measurement tolerances to be used in comparing the electrical images generated by running the test script on SUT 106 against the equivalent reference electrical images. In FIG. 5, a reference value R is defined based on the measurements and/or data collected from the equivalent reference electrical images. Any deviations from the reference value are categorized based on the extent of the deviation. This allows STT 100 to be used in a proactive manner by labeling any tolerance deviations based on the extent of the deviation. For example, very slight deviations (e.g., [R; R+2%] are categorized as merely ageing wires, in which case, the absence of a defect is noted by a comparison of the equivalent reference value to the value obtained from SUT 106. Deviations that are more substantial (e.g., [R+2%; R+4%]) are categorized as a proactive warning, in order to alert TM user 104 of wires in which one or more defects may be occurring in the near future, in which case, the absence of a defect is noted by a comparison of the equivalent reference value to the value obtained from SUT 106. Substantial deviations (e.g., [>R+4%]) are categorized as defects or faults, and are indicated as defects in the analysis. Please note that these tolerances in FIG. 5 are exemplary only, and other deviation percentages may be used by STT 100 when comparing the equivalent reference value to the value obtained from SUT 106. Further, different colors, hatching, etc. may be used when displaying on the display interface the values obtained from SUT 106 in order to provide clearly discernable information regarding the presence or absence of one or more wiring defect.

As a result, TM 102 detects and locates one or more defect or fault in SUT 106 by analyzing whether measurements or data of a certain line of SUT 106 are within the tolerances defined for the identical system of the healthy aircraft. For example, wire characteristics measurement results and/or distance-to-fault measurement results are generated by TM 102, which provides a comparison of each line of SUT 106 against the equivalent reference data of each line of an ideally healthy aircraft system. FIG. 6 illustrates an exemplary wire characteristics measurement result for SUT 106, where the equivalent reference data for each line of the identical system of the healthy aircraft is also displayed for easy comparison. As illustrated in FIG. 6, a fault is indicated by distinct, vertical hatching at a line (i.e., High Point: H-28; Low Point: Ground) of SUT 106, where the capacitance, measured in Farads (F), is measured as 920.049 pF, while the reference measurement at that line in the identical system of the healthy aircraft is measured as 1.055 nF. Following the tolerance measurement standard illustrated in FIG. 5, it is apparent that the measurement at line H-28 in SUT 106 of 920.049 pF is greater than 0.4% of the equivalent reference value of 1.055 nF measured in the identical system of the healthy aircraft. Accordingly, the wire characteristics measurement results recorded by TM 102 indicate the existence of one or more fault or defect in said line of SUT 106.

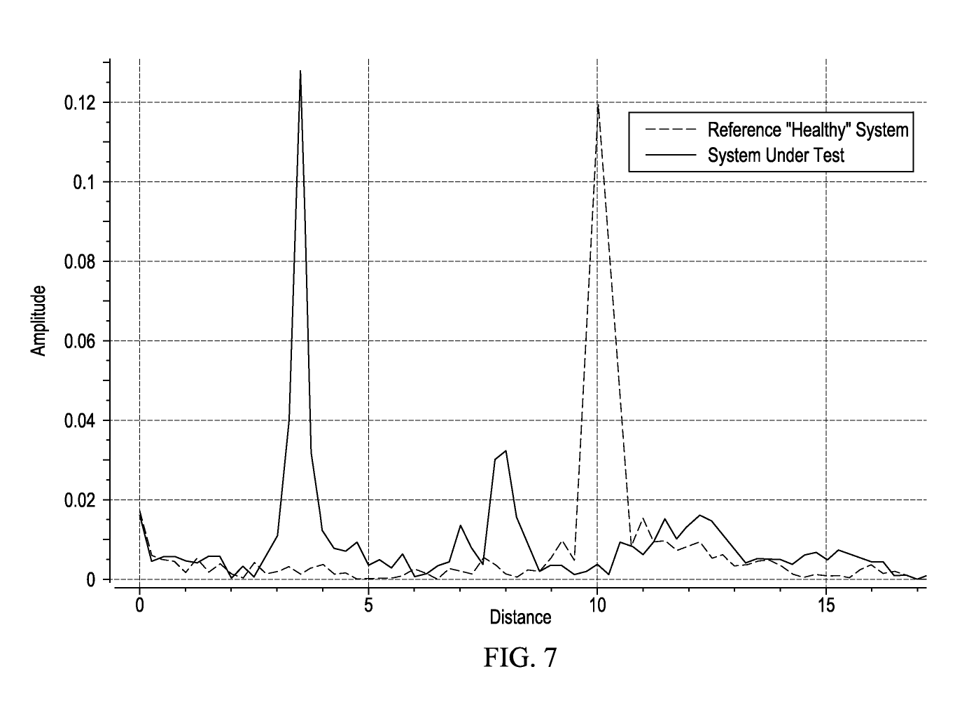

FIG. 7 illustrates exemplary distance-to-fault measurement electrical image results of a line of SUT 106, where the corresponding line of the identical system of the healthy aircraft is also illustrated for comparison purposes. As seen in FIG. 7, an amplitude spike at 10 meters along the healthy line (i.e., High Point: J21-4; Low Point: Ground) is representative of a “healthy” disruption, e.g., connector, pin, interface, etc. (See, FIG. 4). By comparison, in FIG. 7, an amplitude spike occurs at 3.5 meters along the equivalent line in SUT 106, rather than at 10 meters. Since the reference data indicates that a spike should only occur at 10 meters alone the line, this spike in the line of SUT 106 is representative of a defect located 3.5 meters. For example, this defect comprises a pin not being properly inserted or crimped. Accordingly, the distance-to-fault measurement electrical image results enable a technician or engineer to quickly locate the aircraft panel at which the 3.5 meter mark of the line represented in FIG. 7 resides and remedy the defect by replacing the pin, repairing the wire, etc.

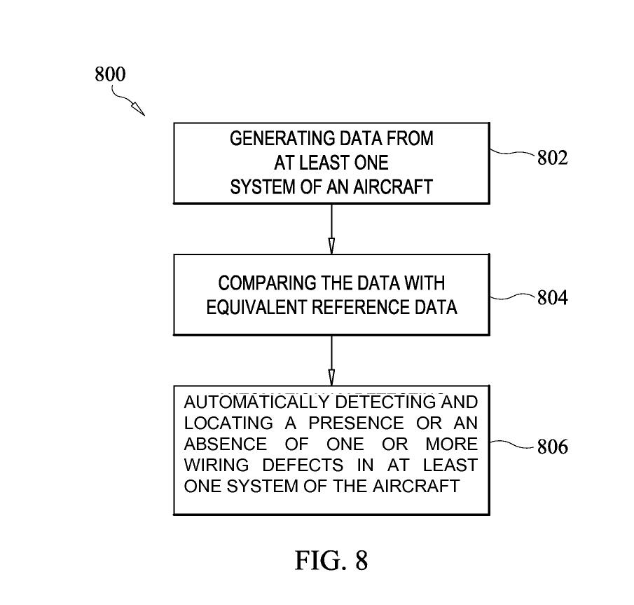

FIG. 8 is a diagram illustrating an exemplary process for detecting and locating one or more wiring defect in at least one dedicated aircraft system, according to an embodiment of the subject matter described herein. In some embodiments, exemplary process 800, or portions thereof, are performed by or at computing platform 100 (e.g., a system testing tool), TM 102, and/or another node or module.

At step 802, data is generated from a system under test or SUT 106. For example, a STT 100 or TM 102 generates data from SUT 106. In some aspects, the data generated from SUT 106 comprises electrical images, such as, for example, wire characteristics measurement electrical images and/or distance-to-fault measurement electrical images. The wire characteristics measurement electrical images are, in some embodiments, RLC measurement images, while the distance-to-fault measurement electrical images are, in some embodiments, reflectometric images.

In some embodiments, generating the data further comprises comparing in real time the data generated from SUT 106 to a system configuration of SUT 106.

In some embodiments, the data from SUT 106 is generated by STT 100 and or TM 102 launching a test script to run a test, where the test script generates the data from SUT 106.

At step 804, the generated data is compared with equivalent reference data. For example, STT 100 or TM 102 compares the data generated from SUT 106 against reference data generated from an equivalent system of another aircraft. In some aspects, the other aircraft is a “healthy” aircraft or one with an equivalent system(s) devoid of any defect. In some embodiments, the equivalent reference data comprises electrical images, such as, for example, wire characteristics measurement electrical images and/or distance-to-fault measurement electrical images. The wire characteristics measurement electrical images are, in some embodiments, RLC measurement images, while the distance-to-fault measurement electrical images are, in some embodiments, reflectometric images.

In some embodiments, the equivalent reference data is generated by STT 100 TM 102 or another computing platform and/or module, launching a test script to run a test, where the test script generates the reference data from the “healthy aircraft”.

In some embodiments, the generated data from SUT 106 and/or the equivalent reference data is stored in at least one storage database. Similarly, the generated data from SUT 106 and/or the equivalent reference data is retrieved from the at least one storage database in order to compare the generated data from SUT 106 with the equivalent reference data.

At step 806, automatic detection and/or location of a presence or an absence of one or more wiring defect in the at least one system of aircraft 10 occurs. For example, STT 100 and/or TM 102 automatically detects the presence or the absence of one or more wiring defect in SUT 106 by analyzing the comparison of the data generated from SUT 106 with the equivalent reference data (i.e., step 804). In some embodiments, the equivalent reference data comprises predetermined tolerance values, such that the presence of the one or more detected wiring defect in SUT 106 results in the generated data falling outside the predetermined tolerance values. Conversely the absence of one or more defect results in the generated data falling within the predetermined tolerance values. For example, where the generated data comprises wire characteristics electrical image(s), the image(s) detects the presence or the absence of one or more defect along a line.

In some embodiments, where there is a presence of one or more wiring defect in SUT 106, STT 100 automatically detects and locates the one or more wiring defect in SUT 106 using the generated data. For example, where the generated data comprises distance-to-fault electrical image(s), these image(s) provide a location for any defect along a line on which the defect is present.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for detecting and locating one or more wiring defect in at least one dedicated system of an aircraft, comprising:
using a system testing tool for:
generating data from the at least one system of the aircraft;
comparing the data with equivalent reference data; and
automatically detecting a presence or an absence of one or more wiring defect in the at least one system of the aircraft.

2. The method of claim 1, wherein automatically detecting the presence or the absence of the one or more wiring defect comprises automatically locating the one or more wiring defect, where the one or more wiring defect is present in the at least one system.

3. The method of claim 1, further comprising storing the generated data from the at least one system of the aircraft and the equivalent reference data in at least one storage database, wherein comparing the data with the equivalent reference data comprises retrieving the equivalent reference data and the generated data from the at least one storage database.

4. The method of claim 1, further comprising launching a test script to run a test, the test script being configured to generate the equivalent reference data and the data from the at least one system of the aircraft.

5. The method of claim 1, wherein the data from the at least one system of the aircraft and the equivalent reference data comprise electrical images.

6. The method of claim 1, wherein the equivalent reference data is from an aircraft system devoid of any defects.

7. The method of claim 1, wherein the system testing tool comprises at least one testing module.

8. The method of claim 1, wherein generating data from the at least one system of the aircraft comprises comparing in real time the data generated from the at least one system of the aircraft to a system configuration of the at least one system.

9. The method of claim 1, wherein the equivalent reference data comprises predetermined tolerance values, such that the one or more detected defect falls outside the predetermined tolerance values.

10. A system for detecting and locating one or more wiring defect in an aircraft, the system comprising:
a testing module configured to:
generate data from the at least one system of the aircraft,
compare the data with equivalent reference data, and
automatically detect a presence or an absence of one or more wiring defect in the at least one system of the aircraft.

11. The system of claim 10, wherein automatically detecting the presence or the absence of the one or more wiring defect comprises automatically locating the one or more wiring defect, where the one or more wiring defect is present in the at least one system.

12. The system of claim 10, wherein the testing module is configured to store the generated data from the at least one system of the aircraft and the equivalent reference data in at least one storage data base, and is configured to retrieve the equivalent reference data and the generated data from the at least one storage database.

13. The system of claim 10, wherein the testing module is configured to launch a test script to run a test, the test script being configured to generate the equivalent reference data and the data from the at least one system of the aircraft.

14. The system of claim 10, wherein the data from the at least one system of the aircraft and the equivalent reference data comprise electrical images.

15. The system of claim 10, wherein the equivalent reference data is from an aircraft system devoid of any defects.

16. The system of claim 10, wherein the testing module is configured to compare in real time the data generated from the at least one system of the aircraft to a system configuration of the at least one system.

17. A non-transitory computer readable medium comprising computer executable instructions embodied in the computer readable medium that when executed by a processor of a computer perform steps comprising:
generating data from at least one system of an aircraft;
comparing the data with equivalent reference data; and
automatically detecting a presence or an absence of one or more wiring defect in the at least one system of the aircraft.

18. The computer readable medium of claim 17, wherein automatically detecting the presence or the absence of the one or more wiring defect comprises automatically locating the one or more wiring defect, where the one or more wiring defect is present in the at least one system.

19. The computer readable medium of claim 17, further comprising launching a test script to run a test, the test script being configured to generate the equivalent reference data and the data from the at least one system of the aircraft.

20. The computer readable medium of claim 17, wherein the equivalent reference data comprises predetermined tolerance values, such that the one or more detected defect falls outside the predetermined tolerance values.
